(19) United States
(12) Patent Application Publication
(10) Pub. No.: US 2003/0214307 A1
(43) Pub. Date: Nov. 20, 2003

(54) Device for detecting partial discharge in power equipment using radiated electromagnetic wave

(76) Inventors: Chang-Won Kang, Hanam-Si (KR); Gil-Soo Choi, Sungnam-Si (KR)

Correspondence Address: David A. Fox, 55 Griffin South Road, Bloomfield, CT, 06002, US

(21) Appl. No.: 10/392,532

(22) Filed: Mar. 20, 2003

(30) Foreign Application Priority Data
Mar. 29, 2002 (KR) UM2002-9517

(51) Int. Cl. H01H 9/50; G01R 31/08

(52) U.S. Cl. 324/536

(57) ABSTRACT

Disclosed is a device for detecting a partial discharge of power equipment. EM (electromagnetic wave) sensors detect EM signals from a partial discharge in a metal clad switchgear, a power cable, and a GIS. EM detectors amplify the signals from the sensors, and output only noise-removed IF signals. A pulse generator integrates the IF-processed EM to compare the integrated value with a previous value, and outputs a pulse according to a partial discharge. An EM level processor compares the IF-processed EM with reference voltages to output EM pulses of a plurality of levels. A waveform shaper shapes the pulses. A controller calculates the average number of pulses per 1 cycle by counting the partial discharge pulses for a predetermined time, receives the waveform-shaped pulses to calculate the partial discharge amount, and transmits the calculated amount, combined with the average number, to an external monitoring system.

### BACKGROUND OF THE INVENTION

1. Field of the Invention

The present invention relates to a system for monitoring insulation deterioration of power equipment such as a metal clad switchgear, a GIS (Gas Insulated Switchgear), and a power cable, and more particularly to a device for detecting a partial discharge from power equipment by detecting radiated electromagnetic waves caused by the partial discharge.

2. Description of the Related Art

Generally, a contact-type fixed monitoring device or portable inspection equipment is used for inspecting and diagnosing power equipment in order to prevent accidents related to the power equipment.

The conventional contact-type fixed monitoring device attaches a sensor on power equipment to detect its deterioration, so it has a problem in that it cannot be applied to already-installed equipment. In addition, the sensor may burn out or the equipment may break down if subjected to a large current due to a grounding short or an incoming surge, so such equipment is always in danger of breakdown.

While being classified into a non-contact type and a contact type, the portable inspection equipment is limited to a one-time inspection, failing to implement a fixed monitoring system. In addition, when power equipment is inspected with the portable equipment in a live line state, there is always a risk of safety accident such as electric shock.

Thus, a manual inspection using human senses is still being used in the actual working field, but this method may bring about a wrong inspection result, depending on the subjectivity of the inspectors. In the case of using a simplified measurement unit such as an infrared thermometer and a corona detector, since it is impossible to inspect and measure covered regions, there are problems in that there is a limitation to early accident prevention, and it is difficult to gain information on the process of equipment deterioration because the inspection is performed after power failure, and excessive special manpower and time is also needed in measuring the deterioration of the power equipment.

Meanwhile, a power cable diagnosis method is classified into a DC leakage current method, a voltage withstand test, etc., which are performed in a dead line state, and a DC voltage overlapping method, a water-tree live-line diagnosis method, and an ultrasonic inspection method, which are performed in a live line state.

The inspection method performed in the dead line state can be used in diagnosing the soundness of the entire power cable line, but it cannot obtain information on the deterioration in a cable termination section (or cable termination kit) and an intermediate connection section (or intermediate joint kit), and, in addition, because the concerned equipment must be stopped, the inspection incurs considerable costs in manpower and materials, and it is also disadvantageous in that deterioration and disorder signals generated from a complex stress in ongoing electric and mechanical operations may be lost.

On the other hand, the live-line inspection method is very advantageous over the dead-line inspection method in that it can detect a deterioration of the line without stopping the equipment operation. However, this inspection method is used in diagnosing the soundness of the entire power cable line, and is not suitable for detection of a local deterioration. Therefore, in these days, an ultrasonic sound detection method is mostly used in detecting deterioration in a cable termination section and an intermediate connection section.

However, the ultrasonic sound detection method also has a problem in that the deterioration detection is possible only after the deterioration has somewhat progressed, due to the characteristics of ultrasonic sensors, and thus it cannot detect the deterioration in its early stage. In addition, the ultrasonic sensor uses a piezoelectric sensor in detecting deterioration signals. There is difficulty in attaching the piezoelectric sensor to a cable connection section with a specific attaching pressure. This may cause an increase of the misdiagnosis rate of the cable deterioration detection, and incur costs in manpower and material for maintenance management of the sensors, depending on the progress of deterioration. Moreover, the conventional ultrasonic sound detection method has a problem in that it is implemented in an analog manner, so the detected data must be reprocessed for transmission to a manager computer located at a remote site.

### SUMMARY OF THE INVENTION

Therefore, the present invention has been made in view of the above problems, and it is an object of the present invention to provide a device for detecting a partial discharge in power equipment using a radiated electromagnetic wave, whereby the deterioration degree of power equipment such as a metal clad switchgear and a power cable can be continuously monitored from a remote site.

It is another object of the present invention to provide a device for detecting a partial discharge in power equipment, which reduces manpower and time required for deterioration measurement of equipment such as a metal clad switchgear, a power cable, and a GIS (Gas Insulated Switchgear).

It is still another object of the present invention to provide a device for detecting a partial discharge in power equipment, which allows detection of the deterioration degree of a power cable, irrespective of the progress of deterioration.

It is a further object of the present invention to provide a device for detecting a partial discharge in power equipment, whereby an electromagnetic wave due to a partial discharge can be easily detected by selecting a sensor suitable for a detection target.

It is yet another object of the present invention to provide a device for detecting a partial discharge in power equipment, whereby the possibility of safety accidents is reduced in detecting deterioration of power equipment, while correctly measuring the deterioration degree of the power equipment.

In accordance with the present invention, the above and other objects can be accomplished by the provision of a device for detecting a partial discharge of power equipment, the device comprising:

a plurality of electromagnetic wave detection sensors, respectively, for detecting electromagnetic wave signals radiated from a partial discharge in a metal clad switchgear, a power cable, and a Gas Insulated Switchgear (GIS);

a plurality of electromagnetic wave detectors for amplifying the signals outputted from the detection sensors, and then outputting only electromagnetic wave signals of intermediate frequency, from which noise is removed;

a pulse generator for integrating an intermediate-frequency-processed electromagnetic wave outputted from one of the electromagnetic wave detectors, comparing the integrated value with a value before the integration, and outputting a pulse according to a partial discharge based on the compared result;

an electromagnetic-wave level processor for comparing the intermediate-frequency-processed electromagnetic wave with each of a plurality of reference voltages, and outputting electromagnetic wave pulses representing a plurality of levels based on the compared result;

a waveform shaper for shaping and outputting a waveform of the pulse according to the partial discharge and a waveform of the electromagnetic wave pulses representing the plurality of levels; and

a controller for calculating an average number of pulses per 1 cycle by counting the waveform-shaped pulses according to the partial discharge for a predetermined time, receiving an input of the waveform-shaped electromagnetic wave pulses representing the plurality of levels to calculate a partial discharge amount in predetermined units, and transmitting the calculated partial discharge amount, combined with the average number of pulses, to an external monitoring system through a communication module.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a view showing the configuration of peripheral blocks of a partial discharge detection device according to an embodiment of the present invention;

FIG. 2 is a detailed block diagram showing the configuration of the partial discharge detection device according to the embodiment of the present invention;

FIG. 3 is a perspective view of an electromagnetic wave detection sensor 110 for power cables shown in FIG. 2;

FIG. 4 is an exemplary sectional view of an electromagnetic wave detection sensor 110 shown in FIG. 3;

FIG. 5 is a view showing the analog circuit arrangement of the partial discharge detection device shown in FIG. 2;

FIG. 6 is a view showing the digital circuit arrangement of the partial discharge detection device;

FIG. 7 is an exemplary view showing the appearance of a GIS electromagnetic-wave detection sensor 130 shown in FIG. 2;

FIG. 8 is a flow chart showing the operation of a controller 170 shown in FIG. 2; and

FIG. 9 is an exemplary view showing a waveform representing the partial discharge amount processed by the controller 170 of FIG. 2.

### DESCRIPTION OF THE PREFERRED EMBODIMENTS

Now, preferred embodiments of the present invention will be described in detail with reference to the annexed drawings. In the following description, a detailed description of known functions and configurations incorporated herein will be omitted when it may make the subject matter of the present invention rather unclear.

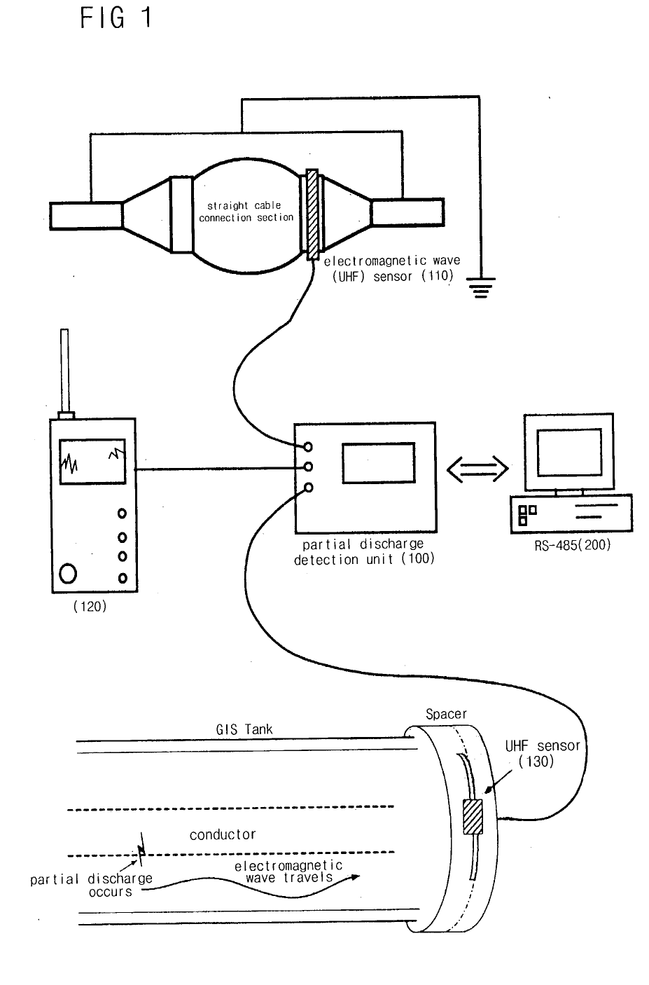

FIG. 1 is a view showing the configuration of peripheral blocks of a partial discharge detection device 100 according to an embodiment of the present invention. The partial discharge detection device 100 can be connected to an electromagnetic wave (UHF) detection sensor 110 for power cables. This detection sensor 110 is mounted on an intermediate connection section of a power cable to detect an electromagnetic wave caused by a defective connection section, a defective semi-conductive layer, an internal foreign material, a void bubble, etc. The partial discharge detection device 100 can also be connected to a GIS electromagnetic-wave detection sensor 130. This detection sensor 130 is located at a solid spacer of a GIS (Gas Insulated Switchgear) to detect an electromagnetic wave caused by a partial discharge resulting from inflow of foreign metallic material into a GIS. In addition, the partial discharge detection device 100 can be connected to an electromagnetic wave detection sensor 120 for metal clad switchgear. This detection sensor is mounted inside a metal clad switchgear to detect an electromagnetic wave generated when power equipment comes to the end of its life, or when improper installation, material breakdown, etc., accelerates its aging process.

The partial discharge detection device 100 calculates the partial discharge amount in units of Coulombs and the average number of pulses of electromagnetic waves detected by one of the three sensors 110, 120, and 130. The detection device 100 displays the calculated result on a display unit or transmits it to a monitoring system 200 located at a remote site through a RS-485 cable.

The monitoring system 200 displays on its monitor the average number of pulses and the partial discharge amount in units of Coulombs inputted through the RS-485 cable, so as to allow a manager to check the status of power equipment located at a remote site. In such a manner, the manager can always check the partial discharge status of a GIS, a power cable, or power equipment located at a remote site.

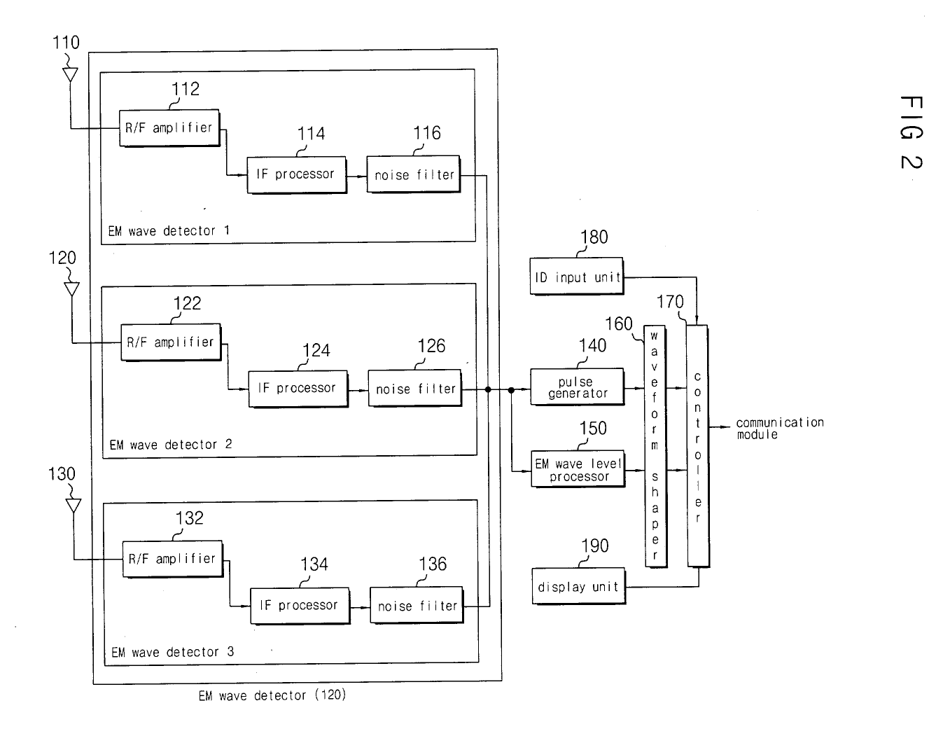

Now, the configuration and operation of the partial discharge detection device 100 will be described referring to FIG. 2.

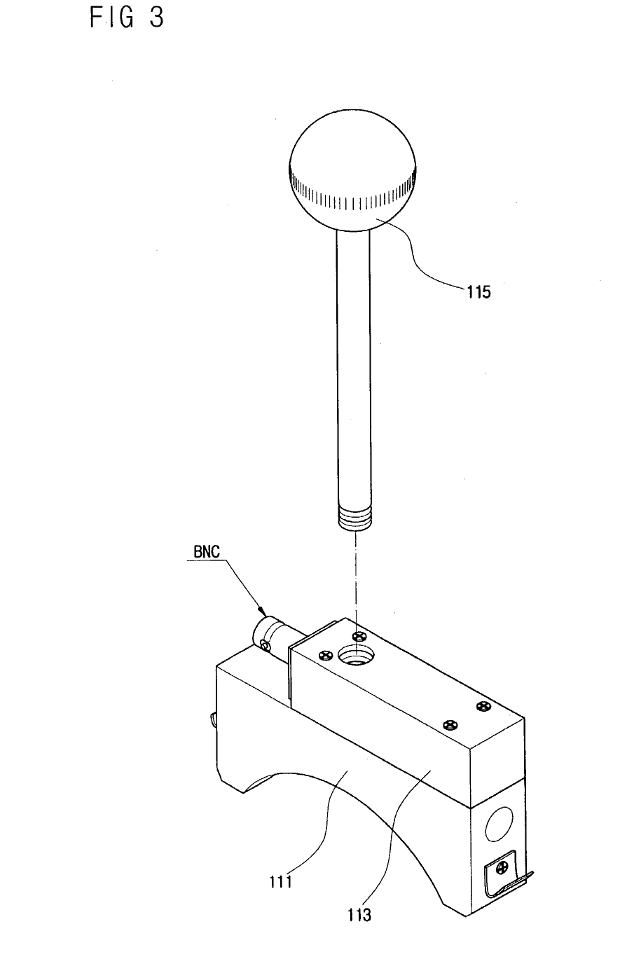

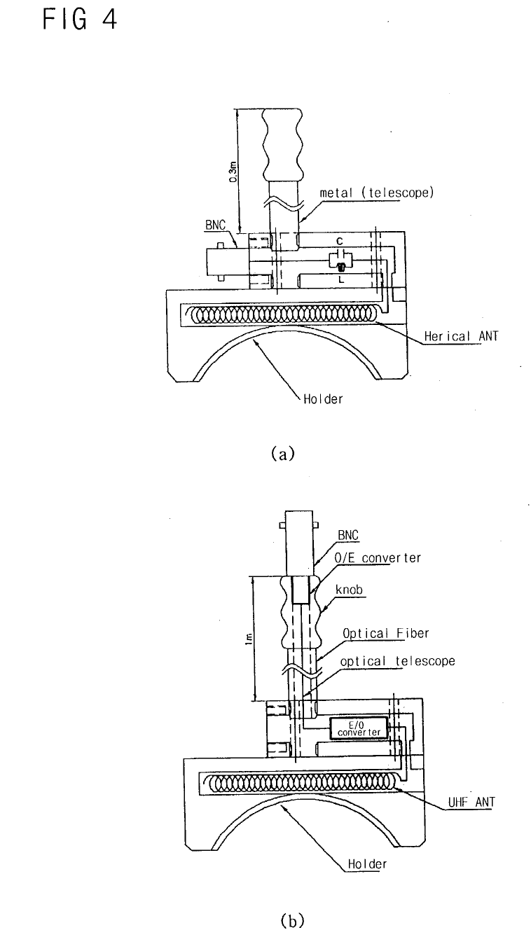

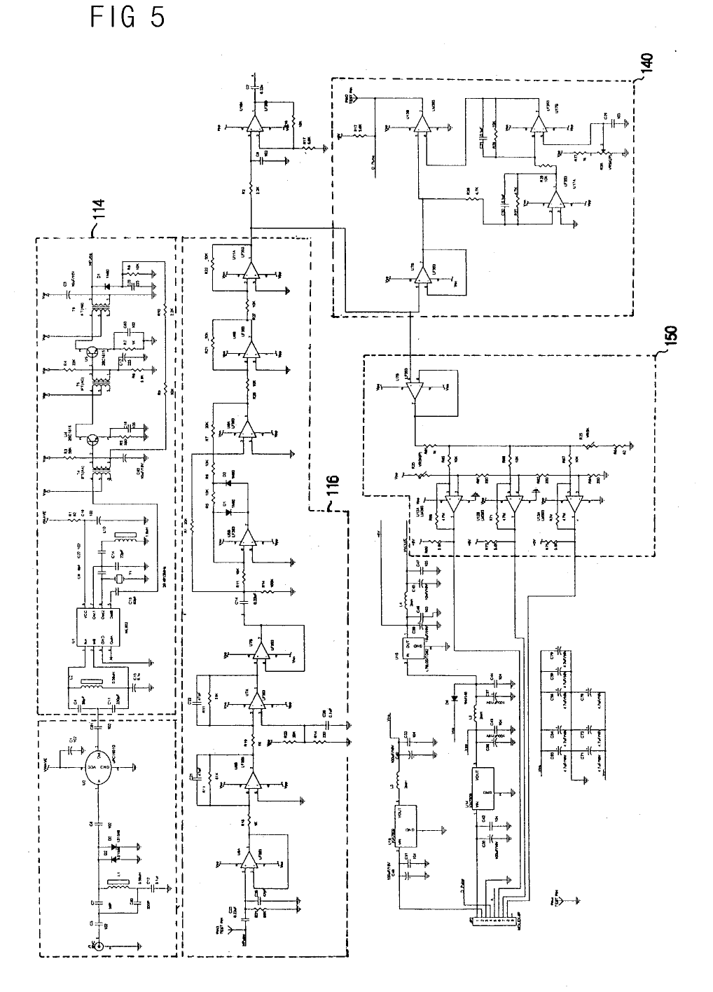

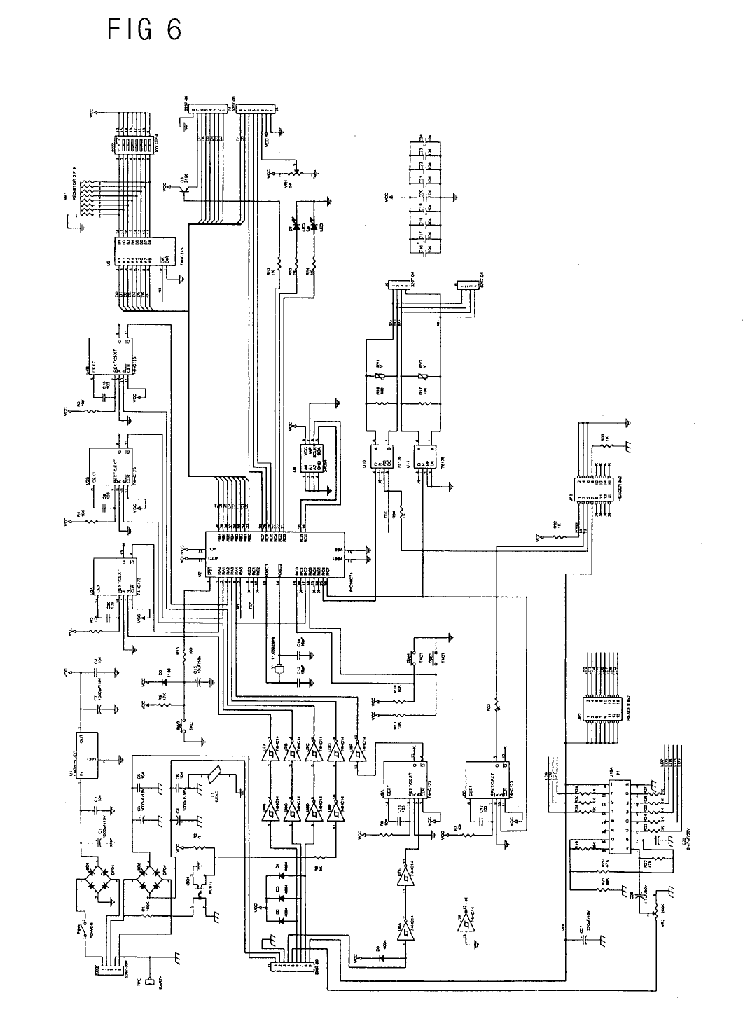

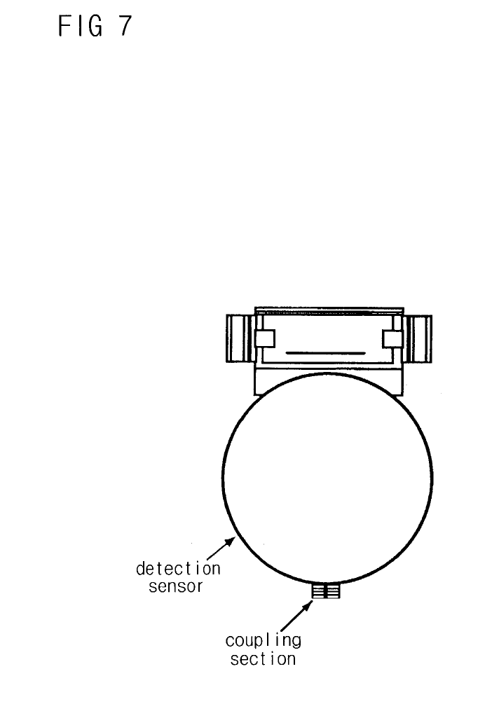

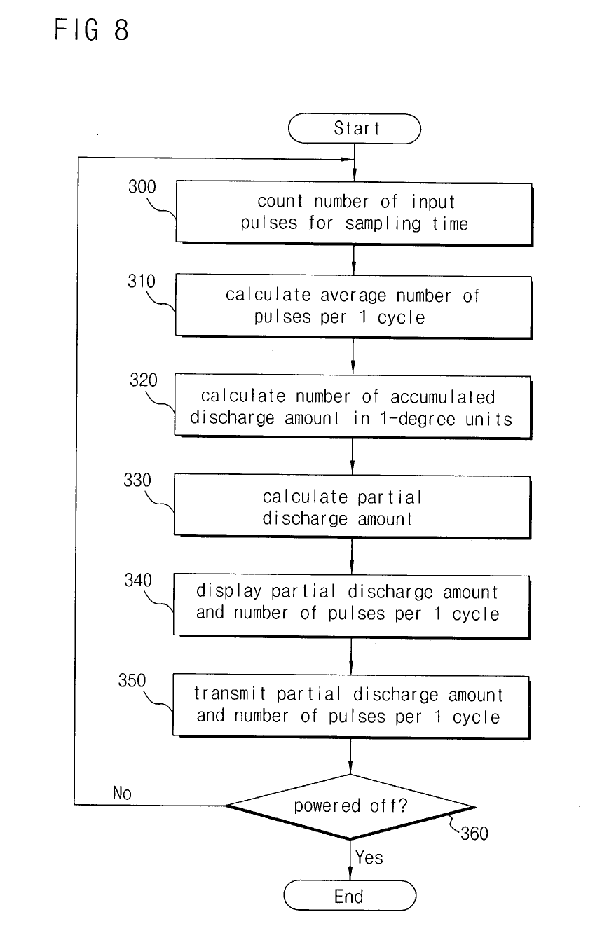

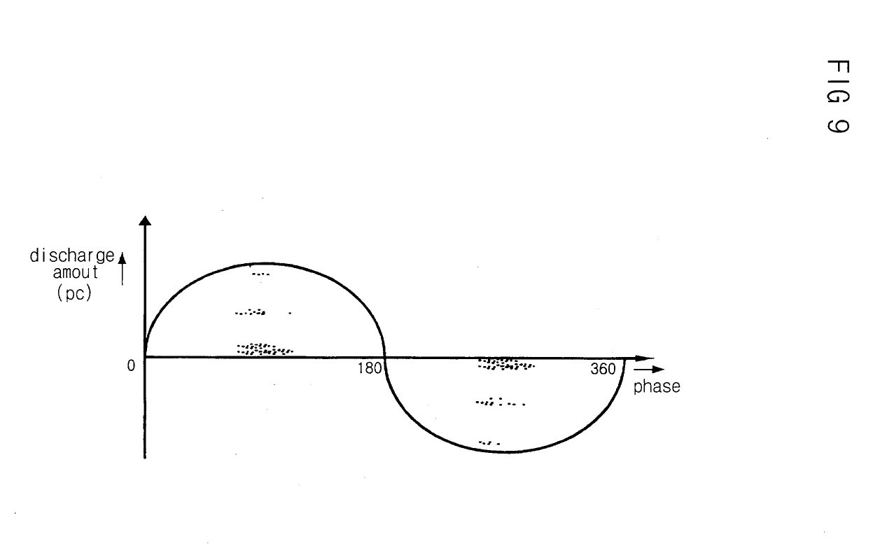

FIG. 2 is a detailed block diagram showing the configuration of the partial discharge detection device according to the embodiment of the present invention. FIG. 3 is a perspective view of the electromagnetic wave detection sensor 110 for power cables shown in FIG. 2. FIG. 4 is an exemplary sectional view of the electromagnetic wave detection sensor 110 shown in FIG. 3. FIG. 5 is a view showing the analog circuit arrangement of the partial discharge detection device shown in FIG. 2. FIG. 6 is a view showing the digital circuit arrangement of the partial discharge detection device. FIG. 7 is an exemplary view showing the appearance of the GIS electromagnetic-wave detection sensor 130 shown in FIG. 2. FIG. 8 is a flow chart showing the operation of a controller 170 shown in FIG. 2. FIG. 9 is an exemplary view showing a waveform representing the partial discharge amount processed by the controller 170 of FIG. 2.

Referring to FIG. 2, the partial discharge detection device 100 according to the embodiment of the present invention includes the sensors 110, 120, and 130, respectively, for detecting electromagnetic wave signals radiated by partial discharges from the three power equipment, i.e., the metal clad switchgear, the power cable, and the GIS. The sensors 110, 120, and 130 can be connected to their unique electromagnetic wave detectors 1, 2, and 3, respectively, according to the user's selection.

In detail, the electromagnetic wave detection sensor 110 for power cables is a band-type electromagnetic-wave detection sensor, and detects only signals in a frequency band of 30 MHz, of electromagnetic wave signals radiated by partial discharges from the power cable, and transmits the detected signal to a RF amplifier 112 located at a rear stage of the sensor 110. Generally, an electromagnetic wave radiated when a partial discharge occurs in power equipment is in a specific frequency band. The frequency band can be found as a narrow band through an AR modeling method. Said frequency band of 30 MHz is a frequency band found through the AR modeling method.

As shown in FIG. 3, the electromagnetic wave detection sensor 110 for power cables includes a cable connection section 111 and a holder 113. The cable connection section 111 has one curved surface matching the surface of the power cable. The holder 113 is mounted on the upper surface of the cable connection section, and a BNC connector is formed on one side of the holder 113. For convenience of work, the holder 113 may have a groove into which one end of a pole having a knob 115 can be screwed. FIG. 4a is a sectional view of such an electromagnetic wave detection sensor 110 for power cables. Referring to FIG. 4a, a helical-type antenna for detecting electromagnetic wave signals is provided inside the cable connection section. An end of the antenna is connected to the BNC connector through amplifier circuits L and C located inside the holder 113. The electromagnetic wave detection sensor 110 having the sectional configuration as shown in FIG. 4a acts to detect an electromagnetic wave caused by a partial discharge, and transmit it to the RF amplifier 112 after amplifying it to a predetermined level.

On the other hand, a straight cable connection section (or straight cable joint kit) is used between cables, so it is relatively safe from high voltage. However, when dielectric breakdown occurs inside the cable connection section, high voltage may affect the surface of the cable connection section, burning out the diagnostic equipment. A cable termination section is spaced from a high voltage terminal by several tens of centimeters or less, so there is a risk of electric shock to a measurer, as well as the cable termination section being constantly exposed to high voltage. In order to shield the equipment from the high voltage, an electrical signal exchanged between the sensor and the diagnostic equipment is required to be converted into an optical signal. FIG. 4a shows a sensor used in the case where there is not always high voltage, like the straight cable connection section. FIG. 4b shows a sensor including a built-in optical conversion unit that is used for a cable termination section or a straight cable connection section in danger of deterioration. The optical conversion unit serves as a protector to secure the safety of the measurer and equipment.

The electromagnetic wave detection sensor 110 of FIG. 4b includes a cable connection section having a curved surface matching the surface of the power cable, and a helical-type antenna (UHF ANT) inserted inside the cable connection section. The sensor 110 further includes a holder which is mounted on the cable connection section and includes therein a first photoelectric (O/E) converter connected to the antenna. A knob is combined to the holder, and a BNC connector is formed on an end of the knob. The knob includes therein a second photoelectric converter (not shown) that is combined between a side of the BNC connector and an optical transmission medium connected to the output terminal of the first photoelectric converter. In other words, the electromagnetic wave detection sensor 110 for power cables shown in FIG. 4b is configured such that it firstly converts an electrical signal detected by the helical-type antenna into an optical signal to be transmitted, and then converts again the converted optical signal into an electrical signal, and outputs it to the RF amplifier 112 through the BNC connector.

Referring to FIG. 2, the electromagnetic wave detector 1 located at the rear stage of the electromagnetic wave detection sensor 110 for power cables functions to differentiate the electromagnetic wave signal from peripheral noise such as a terrestrial broadcast signal. The electromagnetic wave detector 1 includes the R/F amplifier 112, an IF processor 114, and a noise filter 116. The electromagnetic wave detector 1 amplifies the output signal from the sensor, and then modulates only an electromagnetic wave signal, from which noise is removed, into an intermediate frequency and outputs the modulated signal. In more detail, as shown in FIG. 5, the R/F amplifier 112 as a constituent of the electromagnetic wave detector 1 synchronizes and amplifies only an electromagnetic wave in a band of 30 MHz, among the emitted electromagnetic waves in a wide frequency band, through a resonance circuit, and then outputs the amplified signal. The outputted electromagnetic wave signal is modulated into an intermediate frequency of 500 KHz through three Intermediate Frequency Transformers (IFTs) and a modulation circuit in the IF processor 114, and then inputted to the noise filter 116. The IF signal inputted to the noise filter 116 passes through a buffer, an amplifier circuit, and a full wave rectifier circuit as shown in FIG. 5, so that only an electromagnetic wave signal, from which peripheral noise is removed through the full wave rectification, is outputted to a pulse generator 140 and an electromagnetic-wave level processor 150.

An electromagnetic wave detector 2, similar to the electromagnetic wave detector 1, is also provided at the rear stage of the electromagnetic wave detection sensor 120 for metal clad switchgears. The electromagnetic wave detection sensor 120 for metal clad switchgears is configured in a helical antenna type, and detects only a signal in a band of 30 MHz, among electromagnetic wave signals radiated by a partial discharge from a metal clad switchgear, and then outputs it to a R/F amplifier 122 located at the rear stage of the sensor 120. The outputted electromagnetic wave signal in a band of 30 MHz is modulated into an intermediate frequency of 500 KHz through an IF processor 124, and then inputted to a noise removing filter 126. Only an electromagnetic wave signal, from which noise is removed through this noise filter 126, is inputted to the pulse generator 140 and the electromagnetic-wave level processor 150 located at the rear stage of the sensor.

The electromagnetic wave detection sensor 130 for GISs is a band-type electromagnetic wave detection sensor having two ends of pattern antenna type, fixedly coupled to each other by a coupling member, as shown in FIG. 7. This detection sensor 130 detects only a signal in a band of 423 MHz, among electromagnetic wave signals radiated from the inside of the GIS, and transmits it to a R/F amplifier 132 at the rear stage. After being amplified by the R/F amplifier 132, the electromagnetic wave signal in a band of 432 MHz is modulated into an intermediate frequency of 500 KHz, and then inputted to a noise filter 136. Only an electromagnetic wave signal, from which noise is removed by the noise filter 126, is outputted to the electromagnetic-wave level processor 150 and the pulse generator 140 located at the rear stage.

In brief, according to the embodiment of the present invention, an electromagnetic wave radiated from a measurement target is firstly detected using an electromagnetic wave detection sensor suitable for the measurement target, and after only a noise-removed electromagnetic wave signal is extracted from the detected electromagnetic wave signal, a signal processing is performed on the noise-removed signal to calculate and display the partial discharge amount in units of Coulombs and the average number of pulses of electromagnetic waves resulting from the partial discharge.

The following is a more detailed description of the configuration, whereby the signal processing is performed on the noise-removed signal to calculate and display the partial discharge amount in units of Coulombs and the average number of pulses of electromagnetic wave resulting from the partial discharge.

The pulse generator 140 integrates an electromagnetic wave outputted from one of the three electromagnetic wave detectors, and compares the integrated value with a value before the integration, so as to output a pulse resulting from a partial discharge. This pulse resulting from the partial discharge is inputted to the controller 170 through a waveform shaping section 160 to be used in calculating the average number of pulses per 1 cycle.

As shown in FIG. 5, the electromagnetic-wave level processor 150 also compares three reference voltages with electromagnetic waves, respectively, which are outputted from the electromagnetic wave detectors after being subjected to an intermediate frequency processing thereby, and then outputs electromagnetic wave signals representing low, medium, and high levels based on the compared result. These electromagnetic wave signals representing low, medium, and high levels are also inputted to the controller 170 through the waveform shaping section 160.

The waveform shaping section 160 includes a flip flop for time delay and a Schmitt circuit for performing a waveform shaping on the signal outputted from the electromagnetic-wave level processor 150 and the pulse generator 140, as shown in FIG. 6. Through the waveform shaping section 160, both the pulse signal resulting from the partial discharge and the electromagnetic wave signal representing the low, medium, and high levels are shaped into a waveform that can be processed in the controller 170.

The controller 170 calculates the average number of pulses per 1 cycle by counting the pulse due to the partial discharge resulting from the partial discharge for a predetermined time (or a sampling time) according to the procedure as shown in FIG. 8. The controller 170 also calculates the partial discharge amount in units of 1 degree corresponding to the electromagnetic wave signal outputted from the electromagnetic-wave level processor 150, and transmits the calculated partial discharge amount, combined with the average number of pulses, to the monitoring system 200 located at a remote site, while displaying them on a display unit 190 of the partial discharge detection device 100. The controller 170 includes an internal memory (not shown) to store data of the partial discharge amount calculated in real time.

An ID input unit 180 is an 8-pin dip switch used for inputting an ID so that the partial discharge detection device 100 can be discriminated by the monitoring system 200 located at a remote site.

A communication module converts the data of the average number of pulses and the partial discharge amount based on the electromagnetic wave under the control of the controller 170, and transmits the converted data to the monitoring system 200 located at a remote site through the RS-485 cable.

The controller 170 enables the display unit 190 to display various display data. The display unit 190 includes an LED and an LCD.

Now, the procedure of calculating and displaying the average number of pulses and the partial discharge amount based on the electromagnetic wave is described as follows, referring to FIG. 8.

As shown in FIG. 8, the controller 170 counts the number of pulses inputted from the pulse generator 140 for a sampling time in step 300. In the present invention, one cycle of an electromagnetic wave signal is divided into 360 degrees, and each time an electromagnetic wave occurs in 1 degree (for 46 micro sec), the number of pulses is incremented by 1, and such a counting of the number of pulses is performed for 2.5 sec. When the counting of the number of pulses inputted for the sampling time (2.5 sec) is completed, the number of pulses counted for 2.5 sec can be regarded as the average number of pulses per 1 cycle. In such a manner, the controller 170 can calculate the average number of pulses per 1 cycle, which ranges from 0 to 360, in step 310.

The controller 170 moves to step 320 to calculate the number representing the accumulated discharge amount (also referred to as “the number of accumulated discharge amount”) in units of 1 degree based on the low, medium, and high level (or intensity) of the electromagnetic wave signal outputted from the electromagnetic-wave level processor 150. In detail, the number of accumulated discharge amount is calculated by adding values obtained by multiplying pulses within 1 degree having different levels by different variables, respectively. For example, when the level of an electromagnetic wave inputted from the electromagnetic-wave level processor 150 is classified into three levels (level 1, level 2, and level 3), the number N of accumulated discharge amount within 1 degree is calculated by an equation (N=level 1×α+level 2×β+level 3×γ). When the number of accumulated discharge amount in 1 degree is calculated in such a manner, the controller 170 moves to step 330 to calculate a partial discharge amount. The partial discharge amount is calculated by dividing the number of accumulated discharge amount (N=level 1×α+level 2×β+level 3×γ) by the number of pulses (level 1+level 2+level 3).

After calculating the partial discharge amount and the average number of pulses per 1 cycle in steps 310 and 330, the controller 170 moves to step 340 to allow the display unit 190 to display the partial discharge amount and the number of pulses per 1 cycle. Next, in step 350, the controller 170 transmits the partial discharge amount and the number of pulses per 1 cycle to the monitoring system 200 located at the remote site through the communication module.

The partial discharge amount and the number of pulses per 1 cycle displayed on the display unit 190 and the monitoring system 200 are shown in the following Table 1 as an example.

[TABLE 1]

| | | Evaluation | |
|---|---|---|---|
| | | Criteria | |
| Measured Item | Normal | Care Required | Abnormal |
| Time Difference | 8250 or more | 90 to 8250 | 90 or less |
| Number of EM waves | 180 or less | 180 to 240 | 240 or more |
| EM wave discharge | 50 or less | 50 to 70 | 70 or more |
| amount | | | |

The maximum number of pulses per 1 cycle is 360. If the number of electromagnetic waves (# of EM waves), which represents the number of pulses per 1 cycle, is 240 or more, it is considered that a malfunction occurs in the power equipment, as shown in Table 1, and if the number is in the range of 180 to 240, it is considered that the power equipment needs a checkup. If the “EM wave discharge amount” representing the partial discharge amount is 70 or more, it is considered that a malfunction occurs in the power equipment, and if it is in the range of 50 to 70, it is considered that the power equipment needs a checkup.

The partial discharge amount based on the electromagnetic wave can also be expressed by a waveform of FIG. 9. FIG. 9 is an exemplary view showing the waveform representing the partial discharge amount processed by the controller 170 of FIG. 2.

It can be seen from FIG. 9 that there are electromagnetic waves having three different intensities, caused by the partial discharge, around 90 and 270 degrees of the phase of the electromagnetic wave. If the detection time increases, the number of electromagnetic waves around the phase of 90 and 270 degrees will increase.

Referring to the waveform of FIG. 9, the manager or operator can check the degree of deterioration of the power cable or the position and status of the power equipment where a partial discharge occurs.

As apparent from the above description, the present invention has the following advantages. The deterioration degree of power equipment can always be monitored from a remote site, while significantly reducing use of skilled manpower and time required for deterioration measurement of the power equipment. In addition, because the position of equipment where a partial discharge occurs can be found, the possibility of safety accidents can be reduced in inspecting the power equipment, while achieving an easy maintenance management.

Moreover, since an electromagnetic wave according to a partial discharge can be detected using a sensor suitable for the kind of a measurement target, the system compatibility is improved and it is possible to detect the deterioration degree of a power cable, a GIS, and power equipment, irrespective of the progress of deterioration.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A device for detecting a partial discharge of power equipment, the device comprising:
a plurality of electromagnetic wave detection sensors, respectively, for detecting electromagnetic wave signals radiated from a partial discharge in a metal clad switchgear, a power cable, and a Gas Insulator Switchgear (GIS);
a plurality of electromagnetic wave detectors for amplifying the signals outputted from the detection sensors, and then outputting only electromagnetic wave signals of intermediate frequency, from which noise is removed;
a pulse generator for integrating an intermediate-frequency-processed electromagnetic wave outputted from one of the electromagnetic wave detectors, comparing the integrated value with a value before the integration, and outputting a pulse according to a partial discharge based on the compared result;
an electromagnetic-wave level processor for comparing the intermediate-frequency-processed electromagnetic wave with each of a plurality of reference voltages, and outputting electromagnetic wave pulses representing a plurality of levels based on the compared result;
a waveform shaper for shaping and outputting a waveform of the pulse according to the partial discharge and a waveform of the electromagnetic wave pulses representing the plurality of levels; and
a controller for calculating an average number of pulses per 1 cycle by counting the waveform-shaped pulses according to the partial discharge for a predetermined time, receiving an input of the waveform-shaped electromagnetic wave pulses representing the plurality of levels to calculate a partial discharge amount in predetermined units, and transmitting the calculated partial discharge amount, combined with the average number of pulses, to an external monitoring system through a communication module.

2. The device as set forth in claim 1, wherein each of the electromagnetic wave detection sensor for metal clad switchgears and the electromagnetic wave detection sensor for power cables detects only an electromagnetic wave signal in a band of 30 MHz.

3. The device as set forth in claim 2, wherein the electromagnetic wave detection sensor for power cables includes:
a cable connection section whose one side has a curved surface matching a surface of the power cable;
a helical-type antenna inserted in the cable connection section; and
a holder mounted on the cable connection section, the holder having an end on which a BNC connector is formed, the holder including therein an amplifying circuit connected to the BNC connector and the antenna.

4. The device as set forth in claim 3, wherein a groove is defined on an outer surface of the holder so that one end of a pole including a knob formed at its top can be screwed into the groove.

5. The device as set forth in claim 2, wherein the electromagnetic wave detection sensor for power cables includes:
a cable connection section whose one side has a curved surface matching a surface of the power cable;
a helical-type antenna inserted in the cable connection section;
a holder mounted on the cable connection section, the holder including therein a first photoelectric converter connected to the antenna; and
a knob coupled to the holder, the knob having an end on which a BNC connector is formed, the knob including therein a second photoelectric converter coupled between an end of the BNC connector and an optical transmission medium connected to an output end of the first photoelectric converter.

6. The device as set forth in claim 1, wherein the electromagnetic wave detection sensor for GIS is a band-type electromagnetic-wave detection sensor having two ends of pattern antenna type which can be fixedly coupled to each other by a coupling member, and detects only an electromagnetic wave signal in a band of 423 MHz.

7. The device as set forth in claim 1, wherein each of the electromagnetic wave detectors includes at least:
a RF amplifier for synchronizing and amplifying only an electromagnetic wave signal in a band of 30 MHz or 423 MHz, among electromagnetic waves in a wide frequency band radiated by a partial discharge, through a resonance circuit, and then outputting the amplified signal;
an IF processor for modulating the RF-amplified electromagnetic wave signal into a signal of an intermediate frequency of 500 KHz through a plurality of intermediate frequency transformer circuits, and outputting the modulated signal; and
a noise filter for performing a full wave rectification of the intermediate-frequency-processed IF signal to output only an electromagnetic wave signal from which noise is removed.
